(19) United States
(12) Patent Application Publication
(10) Pub. No.: US 2023/0320138 A1
(43) Pub. Date: Oct. 5, 2023

(54) LIGHT EMITTING DISPLAY APPARATUS

(71) Applicant: LG Display Co., Ltd., Seoul (KR)

(72) Inventors: Chungryeol Yoo, Daegu (KR); Soonho KWON, Daegu (KR); Jaehee KIM, Ulsan (KR)

(73) Assignee: LG Display Co., Ltd., Seoul (KR)

(21) Appl. No.: 17/993,703

(22) Filed: Nov. 23, 2022

(30) Foreign Application Priority Data
Mar. 31, 2022 (KR) 10-2022-0040466

(51) Int. Cl. H10K 59/122; H10K 59/40; H10K 50/844; G06F 3/044; G09G 3/3266; H10K 59/131

(52) U.S. Cl. CPC H01L 27/3246; H01L 27/323; H01L 51/5253; G06F 3/0447; G09G 3/3266; H01L 27/3276; G09G 2310/0297; G09G 2330/06

(57) ABSTRACT

Discussed is a light emitting display apparatus that can include a substrate including an active area and a non-active area adjacent to the active area, a planarization layer in the active area and in a first part of the non-active area, a bank layer, a light emitting diode layer, and a first pattern disposed on the planarization layer, and a second pattern and a dam disposed in a second part adjacent to the first part of the non-active area, the second pattern and the dam having different heights.

### CROSS-REFERENCE TO RELATED APPLICATION

This application claims priority to Korean Patent Application No. 10-2022-0040466 filed on Mar. 31, 2022, in the Korean Intellectual Property Office, the entire contents of which is hereby expressly incorporated by reference into the present application.

### BACKGROUND OF THE DISCLOSURE

### Field

The present disclosure relates to a light emitting display apparatus, and more particularly, to a light emitting display apparatus which controls a flow of a protection layer disposed on a light emitting diode layer and improves a sensitivity of a touch line disposed in an outer peripheral area of the light emitting display apparatus.

### Discussion of the Related Art

A recent display apparatus, which is capable of displaying various information and can interact with a user who sees the information, needs to have various sizes, various shapes, and various functions.

Examples of the display apparatus include a liquid crystal display device LCD, an electrophoretic display device FPD, a light emitting diode display device LED, and the like.

The light emitting display apparatus LED is a self-emitting display device so that a separate light source is not necessary, unlike the liquid crystal display device LCD. Therefore, the light emitting display apparatus can be manufactured to have light weight and small thickness. Further, since the light emitting display apparatus is driven at a low voltage, it is advantageous not only in terms of power consumption, but also in the color implementation, the response speed, the viewing angle, and the contrast ratio CR, so that it is being studied as next generation displays.

When the light emitting display apparatus is an organic light emitting display apparatus, the light emitting diode layer can be an organic light emitting diode layer including an anode, an emission layer, and a cathode. In addition, as the light emitting diode layer, a quantum-dot light emitting diode QLED including quantum dots QD can be further used. Hereinafter, even though the description will be made under the assumption that the light emitting display apparatus is the organic light emitting display apparatus, as an example, the type of the light emitting diode layer is not limited thereto.

The organic light emitting display apparatus displays information on a screen by emitting light from a plurality of pixels including a light emitting diode layer having an emission layer. The organic light emitting display apparatus can be classified into an active matrix type organic light emitting diode display (AMOLED) apparatus or a passive matrix type organic light emitting diode display (PMOLED) apparatus depending on a method of driving a pixel.

The active matrix type organic light emitting diode display (AMOLED) apparatus controls a current flowing in an organic light emitting diode using a thin film transistor (TFT) to display images.

The active matrix type organic light emitting diode display apparatus includes various thin film transistors such as a switching thin film transistor (TFT), a driving TFT connected to the switching TFT, and an organic light emitting diode (OLED) connected to the driving TFT.

A gate electrode, a source electrode, a drain electrode, and a semiconductor layer which configure various TFTs having various purposes and a large number of electrode lines connected thereto are disposed and a planarization layer is provided on the thin film transistor.

A light emitting diode layer is disposed on the planarization layer. The light emitting diode layer can include an anode electrode (e.g., an anode) which is a pixel electrode, an emission layer, and a cathode electrode (e.g., a cathode).

The organic light emitting display apparatus uses an organic material for the emission layer. During the process of injecting electrons and holes into the emission layer configured by the organic material through two electrodes (for example, the anode electrode and the cathode electrode) so that the electrons and the holes meet in the emission layer to be recombined, excitons are formed and the light is emitted due to the energy from the excitons.

The electrons and holes are injected through the anode electrode which is a pixel electrode and the cathode electrode which is a common electrode. In order to more smoothly inject the electrons and the holes, the organic layer can include a hole injection layer, a hole transport layer, an electron transport layer, and an electron injection layer and can have a multi-layered structure thereof. The organic light emitting display apparatus can have disadvantages in that there can be deterioration due to internal factors such as deterioration of the electrode and the emission layer due to oxygen or deterioration by the reaction between the emission layer and interface, and deterioration due to external factors such as moisture, oxygen, and ultraviolet rays intruding from the outside. Therefore, packaging and encapsulation of the organic light emitting display apparatus are very important.

A protection layer including at least one inorganic layer and at least one organic layer is formed to protect the light emitting diode layer.

An organic material which configures the protection layer is configured by a polymer material and is formed by a hardening process after being applied on the substrate as a liquid. The organic material has a fluidity before the hardening process so that there is a limitation in that a liquid polymer which configures the organic material intrudes into an area in which a driving circuit is formed in an outer periphery of the substrate to cause a driving failure or a defect.

In order to provide more various useful functions to the users using the light emitting display apparatus, a touch display apparatus has been developed, and which provides a touch-based input method to allow the users to intuitively and easily input information or instructions by avoiding the usual input method such as a button, a keyboard, or a mouse.

One way to provide a touch display apparatus is to provide a plurality of touch lines disposed on the protection layer to detect the presence of touch or the touch coordinate based on the change in the capacitance formed in the plurality of touch lines formed on a substrate.

A planarization layer, an insulating layer, and a metal line which are disposed below the protection layer in an outer peripheral area of the light emitting display apparatus are etched so that steep inclinations and steps can be formed. Therefore, there are limitations in that the edge of the protection layer is not applied with the protection layer or a thickness thereof is sharply reduced. Accordingly, there is a limitation in that a touch sensitivity of the touch line disposed on the protection layer in the outer peripheral area of the light emitting display apparatus is lowered.

Consequently, even though various reviews have been performed to control the flow of the protection layer of the light emitting display apparatus and improve the touch sensitivity in the outer peripheral area of the light emitting display apparatus, it is still insufficient so that development thereof is urgently required.

### SUMMARY OF THE DISCLOSURE

An object to be achieved by the present disclosure is to provide a light emitting display apparatus including a first pattern and a second pattern to more efficiently control a flow of a second protection layer included in the light emitting display apparatus.

Another object to be achieved by the present disclosure is to provide a light emitting display apparatus having a thin bezel by minimizing a design margin of a second protection layer by controlling a flow of the second protection layer of the light emitting display apparatus.

Still another object to be achieved by the present disclosure is to provide a light emitting display apparatus which improves a display quality by minimizing an electric field interference of electrodes disposed above and below a protection layer by improving a thickness of the protection layer in an outer peripheral area.

Still another object to be achieved by the present disclosure is to provide a light emitting display apparatus which improves a touch sensitivity in an outer peripheral area of the light emitting display apparatus including a touch line formed on a protection layer by minimizing a step and a curve of an upper surface of the protection layer.

According to an aspect of the present disclosure, a light emitting display apparatus includes: a substrate including an active area and a non-active area adjacent to the active area; a planarization layer in the active area and a first part of the non-active area; a bank layer, a light emitting diode layer, and a first pattern disposed on the planarization layer; a second pattern and a dam disposed in a second part adjacent to the first part of the non-active area and having different heights.

Objects of the present disclosure are not limited to the above-mentioned objects, and other objects, which are not mentioned above, can be clearly understood by those skilled in the art from the following descriptions.

According to the example embodiment of the present disclosure, the light emitting display apparatus configures a first pattern and a second pattern so that the first pattern and the second pattern control a flow of the second protection layer to minimize the overflowing of the second protection layer to an area in which a driving circuit is formed, thereby improving a display quality and a stability.

According to the example embodiment of the present disclosure, the light emitting display apparatus configures a first pattern and a second pattern so that a design margin is minimized in consideration of an area in which the second protection layer spreads to provide a thin bezel.

According to the example embodiment of the present disclosure, the light emitting display apparatus configures a first pattern and a second pattern so that a thickness of the protection layer disposed in a non-active area NA adjacent to an active area is improved to efficiently block moisture and oxygen entering from a side surface of the light emitting display apparatus.

According to the example embodiment of the present disclosure, the light emitting display apparatus configures a first pattern and a second pattern so that a thickness of the protection layer in a non-active area adjacent to an active area is improved to minimize the electric field interference of the electrodes disposed above and below the protection layer, thereby improving a display quality.

According to the example embodiment of the present disclosure, the light emitting display apparatus minimizes a step and a curve on an upper surface of the protection layer to suppress the loss of the touch line, thereby improving a touch sensitivity of an outer peripheral area of the light emitting display apparatus.

According to an aspect of the present disclosure, a light emitting display apparatus can include a substrate including an active area and a non-active area enclosing the active area; a planarization layer in the active area; a spacer on the planarization layer and in the active area; and a first pattern on the planarization layer and in the non-active area; and a second pattern in the non-active area.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a plan view of a light emitting display apparatus according to an example embodiment of the present disclosure;

FIG. 2 is an enlarged plan view of an outer peripheral area of FIG. 1;

FIG. 3 is a cross-sectional view of a light emitting display apparatus according to an example embodiment of the present disclosure;

FIG. 4 is a photomicrograph of a cross-section of a second protection layer according to a light emitting display apparatus in which a first pattern and a second pattern of FIG. 3 are formed;

FIG. 5 is a cross-sectional view of a light emitting display apparatus according to another example embodiment of the present disclosure;

FIG. 6 is a cross-sectional view of a light emitting display apparatus according to another example embodiment of the present disclosure;

FIG. 7 is a plan view of an outer peripheral area of a light emitting display apparatus including a touch sensor layer and a touch line according to another example embodiment of the present disclosure; and

FIG. 8 is a cross-sectional view of an outer peripheral area of a light emitting display apparatus including a touch sensor layer and a touch line according to another example embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure. Therefore, the present disclosure will be defined only by the scope of the appended claims.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”. When an element or layer is disposed “on” another element or layer, another layer or another element can be interposed directly on the other element or therebetween.

When the relation of a time sequential order is described using the terms such as “after”, “continuously to”, “next to”, and “before”, the order may not be continuous unless the terms are used with the term “immediately” or “directly”.

Although the terms “first”, “second”, and the like are used for describing various components, these components are not confined by these terms. These terms are merely used for distinguishing one component from the other components. Therefore, a first component to be mentioned below can be a second component in a technical concept of the present disclosure.

In describing components of the example embodiment of the present disclosure, terminologies such as first, second, A, B, (a), (b), and the like can be used. The term is used to distinguish a component from the other component but a nature, an order, or the number of the components is not limited by the terminology. When a component is “linked”, “coupled”, or “connected” to another component, the component can be directly linked or connected to the other component. However, unless specifically stated otherwise, it should be understood that a third component can be interposed between the components which can be indirectly linked or connected.

It should be understood that “at least one” includes one or more all combinations of associated components. For example, “at least one of first, second, and third components” means that not only a first, second, or third component, but also all combinations of two or more of first, second, and third components are included.

In the present disclosure, “apparatus” can include a display apparatus which includes a display panel and a driver for driving the display panel, such as a liquid crystal module (LCM) or an organic light emitting display module (OLED module). Further, the “apparatus” can further include a set electronic device or a set device (or a set apparatus) which is a complete product or a final product including an LCM, or an OLED module, such as a notebook computer, a television, or a computer monitor, an automotive device for vehicle or equipment device including another type of vehicle and a mobile electronic device including a smart phone or an electronic pad.

Accordingly, the apparatus of the present disclosure can include not only a display apparatus itself such as an LCM, or an OLED module, but also an applied product or a set apparatus which is a final consumer device including the LCM, the OLED module, or the like.

In some example embodiments, the LCM or the OLED module configured by the display panel and the driver is represented as a “display apparatus” and an electronic apparatus as a complete product including the LCM or the OLED module is represented as a “set apparatus”. For example, the display apparatus can include a liquid crystal LCD or an organic light emitting OLED display panel and a source PCB which is a controller for driving the display panel. The set apparatus can further include a set PCB as a set controller which is electrically connected to the source PCB to drive the entire set apparatus.

As the display panel used in the example embodiment of the present disclosure, any type of display panel such as a liquid crystal display panel, an organic light emitting diode (OLED) display panel, and an electroluminescent display panel can be used, but the example embodiment is not limited thereto. For example, the display panel can be a display panel which is vibrated by a vibrating device according to an example embodiment of the present disclosure to generate a sound. The display panel applied to the display apparatus according to the example embodiment of the present disclosure is not limited to a shape or a size of the display panel.

The features of various embodiments of the present disclosure can be partially or entirely adhered to or combined with each other and can be interlocked and operated in technically various ways, and the embodiments can be carried out independently of or in association with each other.

Hereinafter, the example embodiment of the present disclosure will be described with reference to the accompanying drawings and examples as follows. Scales of components illustrated in the accompanying drawings are different from the real scales for the convenience of description, so that the scales are not limited to those illustrated in the drawings.

Hereinafter, various example embodiments of the present disclosure will be described in detail with reference to accompanying drawings. All the components of each light emitting display apparatus according to all embodiments of the present disclosure are operationally coupled and configured.

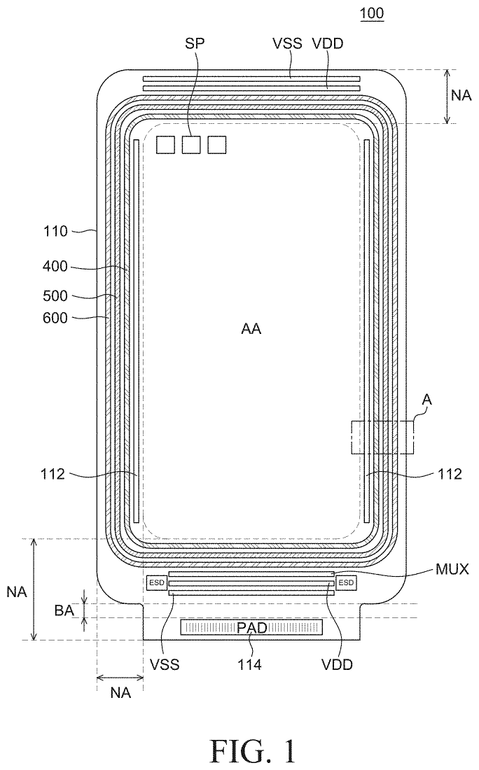

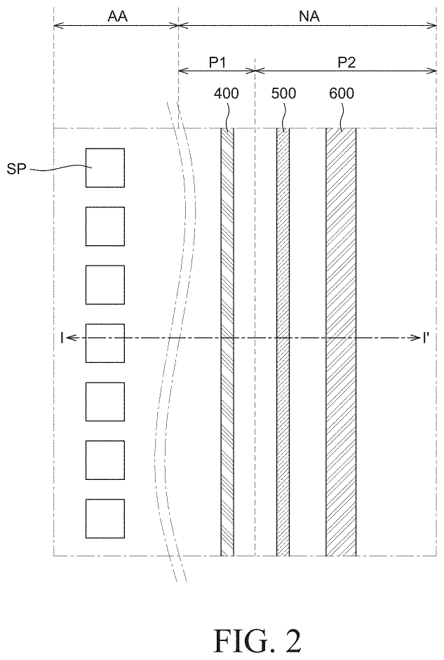

FIG. 1 is a plan view of a light emitting display apparatus according to an example embodiment of the present disclosure. FIG. 2 is an enlarged plan view of an outer peripheral area of FIG. 1.

Referring to FIGS. 1 and 2, a light emitting display apparatus 100 according to an example embodiment of the present disclosure includes a substrate 110, a first pattern 400, a second pattern 500, and a dam 600 in a non-active area NA. Further, it is to be understood that the light emitting display apparatus 100 includes a plurality of gate lines, a plurality of data lines, and other elements including a plurality of thin film transistors (TFT) that are connected to a plurality of pixels and/or a plurality sub pixels SP that enable light emitting display apparatus 100 to properly operate.

Thus, light emitting display apparatus 100 can further include various additional elements to generate various signals or drive a plurality of sub pixels SP in an active area AA. For example, one or more driving circuits for controlling the display panel can be included in the light emitting display apparatus 100. The driving circuit for controlling (or driving) the sub pixels SP includes a gate driver, data signal lines, a multiplexer MUX, an electrostatic discharge ESD circuit, a high potential voltage line VDD, a low potential voltage line VSS, an inverter circuit and the like. The light emitting display apparatus 100 can also include an additional element other than a function to drive each sub pixel SP. For example, the light emitting display apparatus 100 can include additional elements which provide a touch sensing function, a user authentication function (for example, fingerprint recognition), a multilevel pressure sensing function, a tactile feedback function, or the like. The above-mentioned additional elements can be located in the non-active area NA or an external circuit which is connected to the connecting interface.

The substrate 110 can include an active area AA and a non-active area NA. The non-active area NA of the substrate can be adjacent to the active area AA and disposed in the outside from the active area AA.

The outer peripheral area A can be an edge area of the substrate 110. For example, the outer peripheral area A can include an end (or one side) of the active area AA and the non-active area NA.

The active area AA is an area where a plurality of sub pixels SP are disposed to display images. Each of the plurality of sub pixels SP is an individual unit which emits light. The plurality of sub pixels SP includes a red sub pixel SP, a green sub pixel SP, a blue sub pixel SP, and/or a white sub pixel SP, but is not limited thereto.

In each of the plurality of sub pixels SP, an organic light emitting diode and a driving circuit are formed. For example, in the plurality of sub pixels SP, a display element for displaying images and a driving circuit for driving (or controlling) the display element can be disposed.

One sub pixel SP can include a plurality of transistors, a capacitor, and a plurality of wiring lines. For example, the sub pixel SP can be configured by two transistors and one capacitor 2T1C, but is not limited thereto so that a sub pixel to which 3T1C, 4T1C, 5T1C, 6T1C, 7T1C, 3T2C, 4T2C, 5T2C, 6T2C, 7T2C, or 8T2C is applied can also be implemented.

The non-active area NA is an area where no image is displayed and various wiring lines and driving circuits for driving the plurality of sub pixels SP disposed in the active area AA are disposed. For example, in the non-active area NA, various ICs such as a gate driver and a data driver and driving circuits can be disposed. The non-active area NA in which images are not displayed can be an area in which images are not displayed. For example, the non-active area NA can be a bezel area, but is not limited to the terminology.

The non-active area NA can be an area which encloses the active area AA as illustrated in FIG. 1. The non-active area NA can be an area extending from the active area AA. Alternatively, the non-active area NA can be an area in which a plurality of sub pixels SP are not disposed, but is not limited thereto.

The active area AA can be referred to as a display area and the non-active area NA can be referred to or represented as a bezel area or simply a bezel, but are not limited to the terminologies.

Even though in FIG. 1, it is illustrated that the non-active area NA encloses a quadrangular active area AA, a shape of the active area AA and a shape and placement of the non-active area NA adjacent to the active area AA are not limited to the example illustrated in FIG. 1. The active area AA and the non-active area NA can have shapes suitable for a design of an electronic device including the light emitting display apparatus 100. In case of a display apparatus which is wearable by a user can have a circular shape such as a normal watch and the concepts of the example embodiments of the present disclosure can also be applied to a free-form display apparatus which is applicable to a vehicle dashboard. For example, an example shape of the active area AA can be a pentagon, a hexagon, an octagon, a circle, or an oval, but is not limited thereto.

A bending area BA can be provided in a part of the non-active area NA. The bending area BA can be provided between the active area AA and a pad unit 114 located in the non-active area NA. Further, the bending area BA can be an area in which a connection line unit is formed.

The bending area BA is an area in which a part of the substrate 110 can be bent to dispose the pad unit 114 and an external module bonded to the pad unit 114 on a rear surface of the substrate 110. For example, as the bending area BA can be bent toward a rear surface of the substrate 110, the external module bonded to the pad unit 114 of the substrate 110 moves to the rear surface of the substrate 110 so that the external module is not visible as seen from the upper portion of the substrate 110. Further, as the bending area BA is bent, the size of the non-active area NA visible from the upper portion of the substrate 110 is reduced so that a narrow bezel can be implemented. In the present disclosure, it is illustrated that the bending area BA is in the non-active area NA, but is not limited thereto. For example, the bending area BA can be located in the active area AA to bend the active area AA in various directions so that the bending area BA located in the active area AA also has the effect mentioned in the present disclosure.

The pad unit 114 can be disposed at one side of the non-active area NA. The pad unit 114 is a metal pattern to which the external module, for example, a flexible printed circuit board FPCB and a chip on film COF are bonded. Even though it is illustrated that the pad unit 114 is disposed at one side of the substrate 110, a shape and a placement of the pad unit 114 are not limited thereto.

The gate driver 112 which supplies a gate signal to the thin film transistor can be disposed at the other side of the non-active area NA. The gate driver 112 includes various gate driving circuits and the gate driving circuits can be directly formed on the substrate 110. In this case, the gate driver 112 can be a gate-in-panel (GIP).

The gate driver 112 can be disposed between the active area of the substrate 110 and the first pattern 400 disposed in the non-active area NA. Alternatively, the gate driver 112 can be disposed between the active area AA of the substrate 110 and the second pattern 500 disposed in the non-active area NA. Alternatively, the gate driver 112 can be disposed between the active area AA of the substrate 110 and the dam 600 disposed in the non-active area NA.

The high potential voltage line VDD, the low potential voltage line VSS, the multiplexer MUX, the electrostatic discharge ESD circuit, and a plurality of connection line units can be disposed between the active area AA and the pad unit 114 disposed in the non-active area NA.

The high potential voltage line VDD, the low potential voltage line VSS, the multiplexer MUX, and the electrostatic discharge ESD circuit can be disposed between the active area AA and the bending area BA.

The connection line unit can be disposed in the non-active area NA. For example, the connection line unit can be disposed in the bending area BA of the non-active area NA in which the substrate is bent. The connection line unit can be a configuration which transmits a signal (voltage) from the external module bonded to the pad unit 114 to the active area AA or a circuit unit such as the gate driver 112. For example, various signals for driving the gate driver 112, such as a data signal, a high potential voltage, and a low potential voltage, can be transmitted through the connection line unit.

The first pattern 400, the second pattern 500, and the dam 600 can be included in the non-active area NA along the active area AA. The first pattern 400, the second pattern 500, and the dam 600 can be disposed along a periphery of the active area AA so as to control the flow of the second protection layer 320, among protection layers disposed on the light emitting diode layer.

The first pattern 400, the second pattern 500, and the dam 600 can be disposed between the active area AA and the pad unit 114. The first pattern 400, the second pattern 500, and the dam 600 can be disposed between the active area AA and the bending area BA.

The first pattern 400, the second pattern 500, and the dam 600 can be disposed between the active area AA and the high potential voltage line VDD, the low potential voltage line VSS, the multiplexer MUX, or the electrostatic discharge ESD circuit.

A material which configures the second protection layer 320 is an organic material (polymer) and is applied on the substrate 110 in a liquid state and then hardened to form the second protection layer 320. The organic material has a low viscosity so that it can be in the liquid state having a high density before being hardened. Accordingly, the organic material has a fluidity to flow in an area in which the driving circuit is formed in the non-active area NA of the light emitting display apparatus 100 before being hardened. When the organic material intrudes into the area in which the driving circuit is formed, there can be a limitation in that a driving failure or a lighting test failure is caused.

Accordingly, the first pattern 400, the second pattern 500, and the dam 600 can be disposed to be adjacent to the active area AA along the periphery of the active area AA.

Accordingly, before the second protection layer 320 is hardened, the overflowing of the second protection layer 320 over the first pattern 400, the second pattern 500, and the dam 600 onto an area where the driving circuit is formed is minimized to suppress the limitation of the driving failure and improve the display quality and the stability.

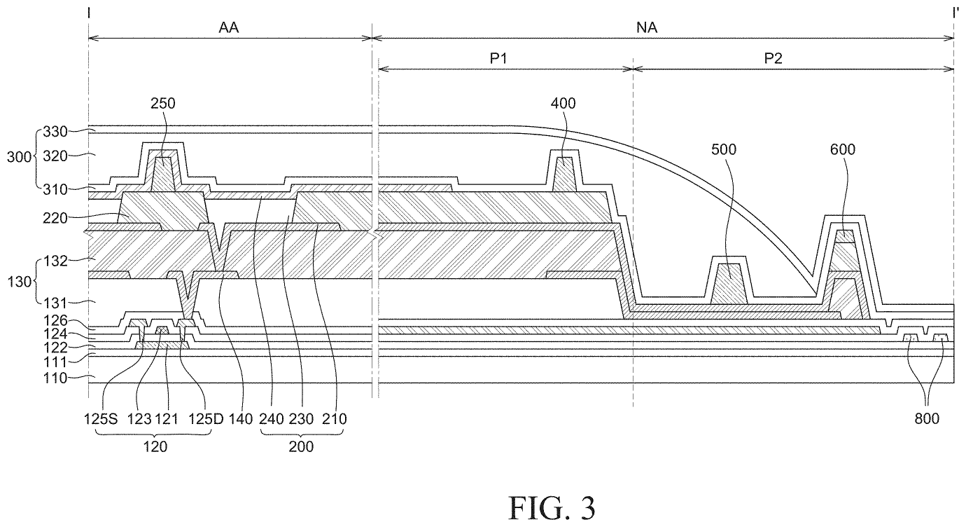

Referring to FIG. 3 to be described below, a crack sensing line 800 can be further included in a part of the non-active area NA of the substrate 110.

The crack sensing line 800 can be disposed between an end point of the substrate 110 and the dam 600 or the crack sensing line 800 can be disposed below the dam 600 and overlap at least a part of the dam.

The light emitting display apparatus 100 can use a flexible substrate which is formed of a plastic material, for example, polyimide, to implement the small thickness and the flexibility.

The substrate formed of polyimide has a low hardness due to the characteristic of the substrate so that the flexibility can be an advantage, but the crack can be easily generated. For example, a laser trimming process for separating the substrate 110 from a support substrate after finishing a manufacturing process of the light emitting display panel on the support substrate which is formed of glass or the external impacts can easily cause the crack. The crack generated on the substrate 110 or the light emitting display apparatus 100 can be gradually increased as the time elapses. The crack which is generated in a specific area of the substrate 110 or the light emitting display apparatus 100 can become a point in which the stress is concentrated by the force to be applied from the outside thereafter. The stress is concentrated on the crack so that the crack can further extend from the non-active area NA to the active area AA. The external oxygen or moisture can permeate due to the crack. The permeation of oxygen or moisture can oxidize the light emitting diode in the active area AA. The oxidation of the light emitting diode can cause a dark spot or pixel shrinkage in the sub pixel SP. In order to suppress the dark spot or shrinkage of the sub pixel, the crack needs to be managed as a major quality factor. Accordingly, in order to check whether the crack is generated in the light emitting display apparatus 100, the crack sensing line 800 can be further disposed in a part of the non-active area NA.

Referring to FIG. 2, the non-active area NA can include a first part P1 and a second part P2.

The first part P1 of the non-active area NA can be an area which encloses the active area AA. The first part P1 of the non-active area NA can be a part adjacent to the active area AA in the non-active area NA. The first part P1 of the non-active area NA can be a part disposed between the active area AA and the second part P2 of the non-active area NA. The first part P1 of the non-active area NA can be an area in which a planarization layer 130 is disposed in the non-active area NA.

The second part P2 of the non-active area NA can be an area which encloses the first part P1 of the non-active area NA. The second part P2 of the non-active area NA can be disposed to be adjacent to the first part P1 of the non-active area NA and enclose the first part P1 of the non-active area NA. The second part P2 of the non-active area NA can be an area of the non-active area NA in which the planarization layer 130 is etched to be removed.

The first part P1 of the non-active area NA can extend from the planarization layer 130 disposed in the active area AA. The second part P2 of the non-active area NA can include an end (or one side) of the light emitting display apparatus from an end point (or one side) of the planarization layer 130. The second part P2 can be disposed outward of the first part P1, and can enclose the first part P2 of the non-active area, as well as the active area AA. A boundary between the first part P1 and the second part P2 can be defined, for example by defining the boundary as where the planarization layer 130 ceases to be present in the non-active area NA

The first pattern 400 can be disposed in the first part P1 of the non-active area NA. The first pattern 400 can be disposed between the active area AA and the second pattern 500 disposed in the second part P2 of the non-active area NA.

The second pattern 500 can be disposed in the second part P2 of the non-active area NA. The second pattern 500 can be disposed along the periphery of the first pattern 400 and can be disposed between the first pattern 400 and the dam 600.

The dam 600 can be disposed along the periphery of the second pattern 500. The dam 600 can be adjacent to the second pattern 500 and can be disposed outward of the first pattern 400 and the second pattern 500.

At least one of each of the first pattern 400, the second pattern 500, and the dam 600 can be disposed. Even though in FIG. 1, one first pattern, one second pattern, and one dam are illustrated, it is not limited thereto, and multiples of each of the first pattern 400, the second pattern 500, and the dam 600 can be provided.

FIG. 3 is a cross-sectional view of a light emitting display apparatus according to an example embodiment of the present disclosure. FIG. 3 is a cross-sectional view taken along the line I-I′ of FIG. 2.

Referring to FIG. 3, a light emitting display apparatus 100 according to an example embodiment of the present disclosure includes a substrate 110, a planarization layer 130, a light emitting diode layer 200, a first pattern 400, a second pattern 500, and a dam 600.

The substrate 110 can support various components of the light emitting display apparatus 100. The substrate 110 can be formed of a glass or a plastic material having flexibility. Other materials may be used.

For example, the substrate 110 can be formed of at least one of polyimide, polyethersulfone, polyethylene terephthalate, and polycarbonate, but is not limited thereto.

When the substrate 110 is formed of a plastic material, for example, when the substrate 110 is formed of polyimide, the manufacturing process of the light emitting display apparatus is performed under a circumstance when a support substrate formed of glass is disposed below the substrate 110. After completing the manufacturing process of the light emitting display apparatus 100, the support substrate can be released or laser-trimmed. Further, after releasing the support substrate, a back plate which supports the substrate 110 can be disposed below the substrate 110.

When the substrate 110 is formed of polyimide, a moisture component permeates the substrate 110 formed of polyimide so that moisture permeation proceeds to the thin film transistor or the light emitting diode layer to degrade the performance of the light emitting display apparatus. In order to suppress the degradation of the performance of the display apparatus due to the moisture permeation, the display apparatus according to the example embodiment of the present disclosure can be configured by two polyimides. Further, an inorganic layer can be formed between two polyimides to block the moisture components from permeating the lower polyimide, so that the reliability of the product performance can be improved. The inorganic layer can be formed by a single layer of silicon nitride SiNx or silicon oxide SiOx or a multi-layer thereof, but is not limited thereto. Other inorganic materials may be used for the inorganic layer.

The substrate 110 can include elements and functional layers formed on the substrate 110, such as a switching element, a driving element (or thin film transistor) connected to the switching element, an organic light emitting diode connected to the driving element (or thin film transistor), and a protection layer. However, it is not limited thereto.

The buffer layer 111 can be disposed on the entire surface of the substrate 110. The buffer layer 111 can improve the adhesiveness between layers formed on the buffer layer 111 and the substrate 110 and block various types of defects such as alkali components leaked from the substrate 110. Further, the buffer layer 111 can delay the diffusion of moisture or oxygen which permeates the substrate 110.

The buffer layer 111 can be formed by a single layer of silicon nitride SiNx or silicon oxide SiOx or a multi-layer thereof. When the buffer layer 111 is formed of a multi-layer, silicon oxide SiOx and silicon nitride SiNx can be alternately formed. Other inorganic materials may be used for the buffer layer 111.

The buffer layer 111 can be omitted based on a type and a material of the substrate 110 and a structure and a type of the thin film transistor 120.

In the light emitting display apparatus 100 according to the example embodiment of the present disclosure, the thin film transistor 120 can be further disposed on the buffer layer 111. The thin film transistor 120 can include a semiconductor pattern 121, a gate electrode 123, a source electrode 125S, and a drain electrode 125D.

The drain electrode 125D is electrically connected to the light emitting diode layer 200 to transmit a current or a signal to the light emitting diode layer 200. Further, a connection electrode 140 is further disposed between the drain electrode 125D and the light emitting diode layer 200 to transmit the current and the signal of the thin film transistor to the light emitting diode layer 200 via the connection electrode 140.

Even though only a driving thin film transistor is illustrated among various thin film transistors which can be included in the light emitting display apparatus 100 for the convenience of description, another thin film transistor such as a switching thin film transistor can also be included in the light emitting display apparatus 100. For the convenience of description, even though it is described that the thin film transistor 120 has a top gate structure, the thin film transistor 120 is not limited to this structure so that the thin film transistor 120 can be implemented by another structure such as a bottom gate structure.

The semiconductor pattern 121 can be disposed on the buffer layer 111. The semiconductor pattern 121 can be formed of a polycrystalline semiconductor. For example, the polycrystalline semiconductor can be formed of a low temperature poly silicon LTPS having a high mobility, but is not limited thereto. When the semiconductor pattern 121 is formed of a polycrystalline semiconductor, the energy consumption is low and the reliability is excellent.

Further, the semiconductor pattern 121 can be formed of an oxide semiconductor. For example, the semiconductor pattern 121 can be formed of any one of indium gallium zinc oxide IGZO, indium zinc oxide IZO, indium gallium tin oxide IGTO, and indium gallium oxide IGO, but is not limited thereto. When the semiconductor pattern 121 is formed of an oxide semiconductor, it has an excellent effect to block the leakage current so that the luminance variation of the sub pixel during the low speed driving can be minimized.

When the semiconductor pattern 121 is formed of the polycrystalline semiconductor or the oxide semiconductor, a partial area of the semiconductor pattern 121 can be doped with impurities.

Further, the semiconductor pattern 121 can be made of amorphous silicon a-Si or various organic semiconductor materials such as pentacene, but is not limited thereto. Other materials can also be used for the semiconductor pattern 121.

The first insulating layer 122 can be disposed on the semiconductor pattern 121. The first insulating layer 122 can insulate the gate electrode 123 from the semiconductor pattern 121.

The first insulating layer 122 can be formed of an inorganic insulating material such as silicon nitride SiNx or silicon oxide SiOx, or other insulating organic material, but is not limited thereto.

The first insulating layer 122 can include a hole to electrically connect the source electrode 125S and the drain electrode 125D to the semiconductor pattern 121, respectively.

The gate electrode 123 can be disposed on the first insulating layer 122. The gate electrode 123 can be disposed so as to overlap the semiconductor pattern 121.

The gate electrode 123 can be formed of a single layer or a multi-layer formed of any one of molybdenum (Mo), copper (Cu), titanium (Ti), aluminum (Al), chrome (Cr), gold (Au), nickel (Ni), neodymium (Nd), and tungsten (W), or an alloy thereof, but is not limited thereto.

A second insulating layer 124 can be disposed on the gate electrode 123.

The second insulating layer 124 can be formed of an insulating material such as silicon nitride SiNx or silicon oxide SiOx or other insulating organic material, but is not limited thereto.

The second insulating layer 124 can include a hole to electrically connect the source electrode 125S and the drain electrode 125D to the semiconductor pattern 121, respectively.

The source electrode 125S and the drain electrode 125D can be disposed on the second insulating layer 124.

The source electrode 125S and the drain electrode 125D can be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof, but is not limited thereto.

For example, the source electrode 125S and the drain electrode 125D can be formed by a triple-layered structure of titanium (Ti)/aluminum (A1)/titanium (Ti) formed of a conductive metal material.

The source electrode 125S and the drain electrode 125D are electrically connected to the semiconductor pattern 121 through the holes of the first insulating layer 122 and the second insulating layer 124.

A protection layer 126 can be disposed above the thin film transistor 120. The protection layer 126 can be disposed in the active area AA and a part of the non-active area NA.

The protection layer 126 can protect the thin film transistor 120. The protection layer 126 can be formed of an inorganic insulating material such as silicon nitride SiNx or silicon oxide SiOx, or other insulating organic material, but is not limited thereto.

The protection layer 126 can include a hole to electrically connect the thin film transistor 120 to the connection electrode 140 or the light emitting diode layer 200. The protection layer 126 is not an essential component, so that it can be omitted depending on the design of the light emitting display apparatus 100.

The planarization layer 130 can be disposed on the protection layer 126. The planarization layer 130 can be disposed to cover the thin film transistor 120.

The planarization layer 130 can protect the thin film transistor 120 disposed therebelow and relieve or planarize a step or a change of elevation due to various patterns.

The planarization layer 130 can be formed of at least one material among organic insulating materials, such as benzocyclobutene BCB, acrylic resin, epoxy resin, phenolic resin, polyamide resin, or polyimide resin, but is not limited thereto. The planarization layer 130 can be disposed as a single layer, but can be disposed as two or more layers in consideration of the placement of various electrodes.

This is because as the light emitting display apparatus 100 evolves to have a higher resolution, various signal lines are increased. Therefore, it is difficult to dispose all the wiring lines on one layer while ensuring a minimum interval so that an additional layer needs to be provided. There is a margin in the placement of the wiring line by providing such an additional layer, which makes it easier to design the electric wire/electrode placement. Further, when a dielectric material is used for the planarization layer configured by a multi-layer, the planarization layer 130 can be utilized to form a capacitance between metal layers.

When planarization layer 130 is provided as a multi-layer, the planarization layer 130 can include a first planarization layer 131 and a second planarization layer 132. But such is not limited thereto, and additional layers can be included in the planarization layer 130.

The connection electrode 140 can be disposed between the first planarization layer 131 and the second planarization layer 132.

A hole can be formed in the first planarization layer 131 and the connection electrode 140 can be formed in the hole so that the thin film transistor 120 and the light emitting diode layer 200 can be electrically connected to each other by means of the connection electrode 140.

For example, one end (or a part) of the connection electrode 140 can be connected to the thin film transistor 120 and the other end (or the other part) of the connection electrode 140 can be connected to the light emitting diode layer 200.

The planarization layer 130 can be disposed in the active area AA and a part of the non-active area NA. For example, the planarization layer 130 can extend from the active area to the first part P1 of the non-active area.

The planarization layer 130 can be etched in the non-active area NA to form a step or an elevation difference.

In the non-active area NA, a part of the non-active area NA where the planarization layer 130 is not removed by the etching process can be defined as the first part P1. A part of the non-active area NA where the planarization layer 130 is removed by the etching process can be defined as the second part P2.

The light emitting diode layer 200 can be disposed on the planarization layer 130. The light emitting diode layer 200 can include an anode electrode 210, an emission layer 230, and a cathode electrode 240.

The light emitting diode layer 200 can be formed by sequentially disposing the anode electrode 210, the emission layer 230, and the cathode electrode 240 on the planarization layer 130.

The anode electrode 210 can be disposed on the planarization layer 130.

The anode electrode 210 can be electrically connected to the drain electrode 125D through the hole of the planarization layer 130. Alternatively, when the light emitting display apparatus 100 further includes the connection electrode 140, the anode electrode 210 can be electrically connected to the drain electrode 125D by means of the connection electrode 140.

The anode electrode 210 can supply holes to the emission layer 230 and can be formed of a conductive material having a high work function.

When the light emitting display apparatus 100 is a top emission type, the anode electrode 210 can be disposed using an opaque conductive material as a reflective electrode which reflects light. The anode electrode 210 can be formed of at least one of silver (Ag), aluminum (Al), gold (Au), molybdenum (Mo), tungsten (W), chrome (Cr), or an alloy thereof. For example, the anode electrode 210 can be formed with a triple layered structure of silver (Ag)/lead (Pb)/copper (Cu), but is not limited thereto.

When the light emitting display apparatus 100 is a bottom emission type, the anode electrode 210 can be disposed using a transparent conductive material through which light passes. For example, the anode electrode 210 can be formed of at least one of indium tin oxide ITO and indium zinc oxide IZO. Other materials, including metals or non-metals can be used for the anode electrode 210.

A bank layer 220 can be disposed on the planarization layer 130 or the anode electrode 210 in the active area AA and the non-active area NA.

The bank layer 220 can divide the plurality of sub pixels SP, minimize the glaring phenomenon or glare, and suppress color mixture at various viewing angles.

The bank layer 220 can be disposed on the planarization layer 130 or the anode electrode 210 in the remaining area excluding an emission area of the anode electrode 210 of the light emitting diode layer 200. The bank layer 220 can have a bank hole which exposes a portion of the anode electrode 210 corresponding to the emission area.

The bank layer 220 can be formed of at least one material among inorganic insulating materials, such as silicon nitride SiNx or silicon oxide SiOx or organic insulating materials, such as benzocyclobutene BCB, acrylic resin, epoxy resin, phenolic resin, polyamide resin, or polyimide resin, but is not limited thereto.

A spacer 250 can be further disposed on the bank layer 220. The spacer 250 can minimize the light emitting display apparatus 100 from being broken due to the external impact by buffering an empty space between the substrate 110 on which the light emitting diode layer 200 is formed and the upper substrate. The spacer 250 can be formed of the same material as the bank layer 220 and simultaneously formed with the bank layer 220, but is not limited thereto.

The first pattern 400, the second pattern 500, and the dam 600 can be disposed in the non-active area NA of the light emitting display apparatus 100. The first pattern 400, the second pattern 500, and the dam 600 can suppress the limitations such as a driving failure caused when the second protection layer 320 of the protection layer 300 intrudes into an area of the non-active area NA in which the driving circuit is formed. Among the first pattern 400, the second pattern 500 and the dam 600, at least the first pattern 400 can be on the planarization layer 130, and can be further disposed on the bank layer 220, which can be the same layer on which the spacer 250 is disposed. However, such is not required, and the first pattern 400 can be disposed on a different layer from that of the spacer 250, as long as at least the first pattern 400 can be located in the non-active area NA and on or above the planarization layer 130.

At least one of each of the first pattern 400, the second pattern 500, and the dam 600 can be formed. In order to implement a thin bezel by minimizing the design margin of the second protection layer while suppressing the overflowing of the second protection layer 320 to the driving element, at least one first patterns 400 and at least one second patterns 500 can be provided so that the number of the first patterns 400 and the second patterns 500 can be at least two, and the number of dams 600 can be at least one.

A material which configures the second protection layer 320 is an organic material (polymer) and is applied on the substrate 110 in a liquid state and then hardened to form the second protection layer 320. The organic material has a low viscosity so that it can be in the liquid state having a high density before being hardened. Accordingly, the organic material has a fluidity to flow in an area in which the driving circuit is formed in the non-active area of the light emitting display apparatus 100 before being hardened. When the organic material intrudes into the area in which the driving circuit is formed, there can be a limitation in that a driving failure or a lighting test failure is caused.

Therefore, the inventors of the present disclosure conducted several experiments to reduce the flow of the organic material until the second protection layer 320 was hardened. The inventors invented a light emitting display apparatus 100 which minimized the flow of the organic material of the second protection layer 320 of the light emitting display apparatus and minimized the driving failure caused by the intrusion of the second protection layer 320 in to an area of the non-active area NA in which the driving circuit was formed, through several experiments.

The first pattern 400, the second pattern 500, and the dam 600 can control the flowability of the organic material of the second protection layer 320. First, the flow of the organic material of the second protection layer 320 is controlled by the first pattern 400 adjacent to the active area AA. When the organic material overflows the first pattern 400, flow of the organic material can be controlled by the second pattern 500 which is secondarily disposed. The second pattern 500 does not allow the organic material to overflow the dam 600.

The dam 600 which is higher than the second pattern 500 is disposed at the outer edge of the second pattern 500 to confine the organic material in the dam 600 so that the spreading (or flowing) of the organic material of the second protection layer 320 into the driving circuit in the non-active area can be blocked by the dam 600 thirdly disposed.

The first pattern 400 can be disposed along the periphery of the active area AA. For example, the first pattern 400 can be adjacent to the active area AA to enclose the active area AA.

The first pattern 400 can be disposed in the first part P1 of the non-active area NA. For example, the first pattern 400 can be disposed on the planarization layer 130 of the non-active area NA which extends from the active area AA.

Since the first pattern 400 is disposed on the planarization layer 130 of the first part P1, the first pattern 400 is disposed in a higher position than the second pattern 500 and the dam 600 and is formed to be more adjacent to the active area AA to more efficiently control the flow of the organic material before the second protection layer 320 is primarily hardened.

Since the first pattern 400 is disposed on the planarization layer 130, the flow of the organic material of the second protection layer 320 in the first pattern 400 disposed in the non-active area NA adjacent to the active area AA is blocked so that the thickness of the second protection layer 320 can be increased after being hardened. The protection layer 300 having an increased overall thickness can efficiently block moisture and oxygen flowing from a side surface of the light emitting display apparatus 100.

The first pattern 400 can be disposed in the first part P1 of the non-active area NA while enclosing the periphery of the active area AA. The first pattern 400 can be disposed to be spaced apart from at least a part of the active area AA.

The first pattern 400 can be structured as a plurality of layers using at least one material. The first pattern 400 can be formed of the same material as the spacer 250 of the active area AA and can be simultaneously formed with the spacer 250, but the material and the forming operation are not limited thereto.

The second pattern 500 can be disposed in the second part P2 of the non-active area NA so as to provide an enclosure at the periphery of the first pattern 400 of the non-active area NA.

The second pattern 500 can be disposed to be at least partially spaced apart from the first pattern 400.

The second pattern 500 blocks the flowing of the organic material which is spread (or flow) from the first pattern 400 to reduce the moving speed of the organic material.

The second pattern 500 can be disposed as a plurality of layers using at least one material. The second pattern 500 can be formed of the same material as the spacer 250 of the active area AA and can be simultaneously formed with the spacer 250, but is not limited thereto.

Even though the dam 600 is disposed in the second part P2 of the non-active area NA, a moving speed of the organic material of the second protection layer 320 is increased due to a height and a slope of a step formed by and an elevation drop due to etching a plurality of planarization layers, insulating layers, and metal lines in the non-active area NA. Therefore, there can be a limitation in that the second protection layer 320 spreads (or flows) to the driving circuit of the non-active area NA before being hardened.

However, the second pattern 500 is disposed in the second part P2 of the non-active area NA, for example, between the first pattern 400 and the dam 600 to suppress or reduce the flow of the organic material of the second protection layer 320. Accordingly, the second pattern 500 reduces a spreading (or flowing) speed of the organic material of the second protection layer 320 to control a spreading (or flowing) distance of the second protection layer 320. Therefore, the limitation such as the driving failure which is caused by the second protection layer 320 which intrudes into the non-active area NA can be suppressed.

Further, the spreading (or flowing) distance of the second protection layer 320 is minimized to minimize a design margin of the second protection layer 320 so that a light emitting display apparatus which has a thin bezel and has an improved reliability can be provided.

The dam 600 can be disposed in the second part P2 of the non-active area NA so as to enclose the periphery of the second pattern 500. The dam 600 can be disposed to be at least partially spaced apart from the second pattern 500.

For example, the dam 600 can be disposed on the second part P2 which is an area in which the planarization layer 130 of the non-active area NA is etched to be removed. At least one or a plurality of dams 600 can be disposed. Even though in FIG. 1, one dam 600 is illustrated, the numerical amount of the dam 600 need not be limited to only one.

The dam 600 can be provided as a single layer or a multi-layer using at least one material.

The dam 600 can be formed as at least one layer using at least one material. For example, the dam can include at least one material among the materials used to dispose the planarization layer 130, the bank layer 220 and the spacer 250.

Alternatively, or additionally, the dam 600 can be sequentially laminated in the non-active area NA to be formed as a multi-layer when the planarization layer 130, the bank layer 220, and the spacer 250 disposed in the active area AA are formed, but is not limited thereto.

The dam 600 can include the same material as the anode electrode 210 disposed in the active area AA.

The emission layer 230 can be disposed on the anode electrode 210. The emission layer 230 can be a layer configured by an organic material which emits light with a specific color. For example, the emission layer 230 can be configured by at least one of a red organic emission layer, a green organic emission layer, a blue organic emission layer, and a white organic emission layer. When the emission layer 230 is configured by the white organic emission layer, a color filter can be further disposed above the light emitting diode layer 200 to provide light of a certain color.

In addition to the emission layer 230, a hole injection layer, a hole transport layer, an electron transport layer, and an electron injection layer can be included, but is not limited thereto, and additional layers or different layers can be included.

The cathode electrode 240 can be disposed on the emission layer 230. The cathode electrode 240 supplies electrons to the emission layer 230 and can be formed of a conductive material, and such a conductive layer can have a low work function.

When the light emitting display apparatus 100 is a top emission type, the cathode electrode 240 can be disposed using a transparent conductive material through which light passes. For example, the cathode electrode 240 can be formed of at least one of indium tin oxide ITO and indium zinc oxide IZO, but is not limited thereto, as various other transparent conductive materials can be used.

Further, the cathode electrode 240 can be disposed using a translucent conductive material through which light passes. For example, the cathode electrode 240 can be formed of at least one of alloys such as LiF/Al, CsF/Al, Mg:Ag, Ca/Ag, Ca:Ag, LiF/Mg:Ag, LiF/Ca/Ag, and LiF/Ca:Ag. Other alloy or compounds can be used as well for the cathode electrode 240.

When the light emitting display apparatus 100 is a bottom emission type, the cathode electrode 240 can be disposed using an opaque conductive material as a reflective electrode which reflects light. For example, the cathode electrode 240 can be formed of at least one of silver (Ag), aluminum (Al), gold (Au), molybdenum (Mo), tungsten (W), chrome (Cr), or an alloy thereof. Other metallic materials can also be used.

The protection layer 300 can be disposed on the light emitting diode layer 200. The protection layer 300 can be disposed in the active area AA and the non-active area NA of the light emitting display apparatus 100.

The protection layer 300 suppresses the permeation of the oxygen and moisture from the outside to suppress the oxidation of a light emitting material and an electrode material. The protection layer 300 can include a first protection layer 310, a second protection layer 320, and a third protection layer 330 which block the permeation of moisture or oxygen.

The first protection layer 310, the second protection layer 320, and the third protection layer 330 can be alternately laminated. The protection layer 300 can be formed of a transparent material to transmit light emitted from the emission layer 230.

The first protection layer 310 and the third protection layer 330 can be additionally formed at the outer edge of the dam 600 disposed in the non-active area NA. For example, the first protection layer 310 and the third protection layer 330 can be disposed between the dam 600 and the edge (or one side) of the substrate 110.

The second protection layer 320 can be formed inward of the dam 600 disposed in the non-active area NA. For example, the second protection layer 320 can be disposed between the dam 600 and the active area AA. Alternatively, or additionally, the second protection layer 320 can be disposed between the dam 600 and the second pattern 500. Accordingly, the second protection layer 320 can be disposed in the active area AA, in the second part P2 of the non-active area NA or both. Also, the protection layer 300 inward of the first pattern and the protection layer outward of the first pattern can have an elevation difference, and a thickness difference of the second protection layer 320 in the first part P1 and the second part P2 of the non-active area NA can be a main reason for the elevation difference. Meanwhile, a thickness of the second protection layer 320 can change in extending outward from the active area AA to the non-active area NA. Nevertheless, the second protection layer 320 need not disposed outward of the dam 600.

The first protection layer 310 and the third protection layer 330 can be formed of at least one inorganic material among silicon nitride SiNx, silicon oxide SiOx, and aluminum oxide AlyOz, among others. The first protection layer 310 and the third protection layer 330 can be formed using a vacuum film forming method such as chemical vapor deposition (CVD) or atomic layer deposition (ALD), but are not limited thereto.

The second protection layer 320 can cover foreign materials, particles, or impurities which can be generated during a manufacturing process. Further, the second protection layer 320 can planarize a surface of the first protection layer 310. For example, the second protection layer 320 can be a particle cover layer, but the second protection layer 320 is not limited to only this terminology.

The second protection layer 320 can be an organic material, for example, a polymer such as silicon oxy carbon SiOCz, epoxy, polyimide, polyethylene, or acrylate. For example, the second protection layer 320 can be a polymer having a viscosity of 20 or lower, but is not limited thereto. Viscosity of 20 or higher may be used based on presence of the second pattern 500 and the dam 600.

The second protection layer 320 can be formed of a thermosetting material or a photo curable material which is hardened by heat or light.

The second protection layer 320 can be formed by various methods such as inkjet coating or slit coating, but is not limited thereto. For example, the second protection layer 320 can be formed on the first protection layer 310 by spraying or dropping a liquid organic material on the first substrate 110 on which the first protection layer 310 is formed, in the active area AA using an inkjet device or a nozzle coating device. A fluid organic material can be formed in an applying area while the spraying nozzle moves on the applying area (or a nozzle is fixed and a subject moves).

After spraying or dropping the organic material, a solvent and moisture can be removed by performing a drying process and a hardening process on the organic material to form a hardened second protection layer 320.

When the liquid organic material is sprayed or dropped on the first substrate 110 in the active area AA, the first pattern 400 formed in the first part P1 and the second pattern 500 formed in the second part P2 of the non-active area NA which encloses the active area AA can effectively block the flow of the organic material of the second protection layer 320. In embodiments of the present disclosure, a surface of the protection layer 300 between the spacer 250 and the first pattern 400 can include a planar portion where the surface is essentially flat. Meanwhile, the surface of the protection layer 300 between the first pattern 400 and the second pattern 500 or the dam 600 can include an uneven portion where the surface is not completely flat or can include irregularities. Based on the flatness of the protection layer 300, a thickness of the protection layer 300 between the spacer 250 and the first pattern 400 can be different from a thickness of the protection layer 300 between the first pattern 400 and the second pattern 500 or between the second pattern 500 and the dam 600. Even so, in certain locations, such as wherein the spacer 250 and the first pattern 400 are located, a thickness of the planarization layer 300 over the spacer 250 can be about the same as a thickness of the planarization layer 300 over the first pattern 400.

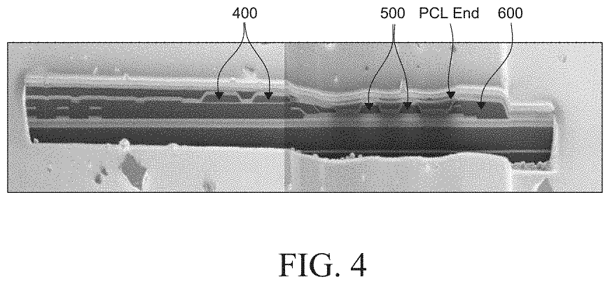

FIG. 4 is a photomicrograph of a cross-section of a second protection layer according to a light emitting display apparatus in which a first pattern and a second pattern of FIG. 3 are formed.

An arrow of FIG. 4 with the label PCL End indicates an end point of the second protection layer 320.

The second protection layer 320 illustrated in FIG. 4 is formed after curing the organic material which configures the second protection layer 320. It is provided that the end point (PCL end) of the second protection layer 320 is formed by passing through the first pattern 400 and the second pattern 500, without passing over the dam 600.

A material which configures the second protection layer 320 has a low viscosity characteristic so that it can be in a liquid state having a high density until the material is hardened. Referring to FIG. 4, the first pattern 400 is primarily disposed to be adjacent to the active area AA to enclose the active area and then the second pattern 500 is secondarily disposed to enclose the first pattern 400. Therefore, it is confirmed that before curing the second protection layer 320, the moving speed of the organic material becomes slow by the first pattern 400 and the second pattern 500 to minimize or eliminate an amount of the organic material of the second protection layer 320 which overflows the dam 600 to spread (or flow) into the non-active area NA.

Further, when the first pattern 400 and the second pattern 500 are not disposed, the significant distance from the active area AA to the dam 600 needs to be set as the design margin of the second protection layer 320. On the contrary, the spreading (or flowing) distance of the second protection layer 320 onto the first pattern 400 and the second pattern 500 which can be configured to be smaller than the width or the height of the dam 600 is minimized to minimize the design margin of the second protection layer 320. By doing this, a light emitting display apparatus with a thin bezel and an improved reliability can be provided. In the present disclosure, “height” may refer to a height from the bottom of a pattern or a dam to the top of said pattern or said dam in a cross sectional view.

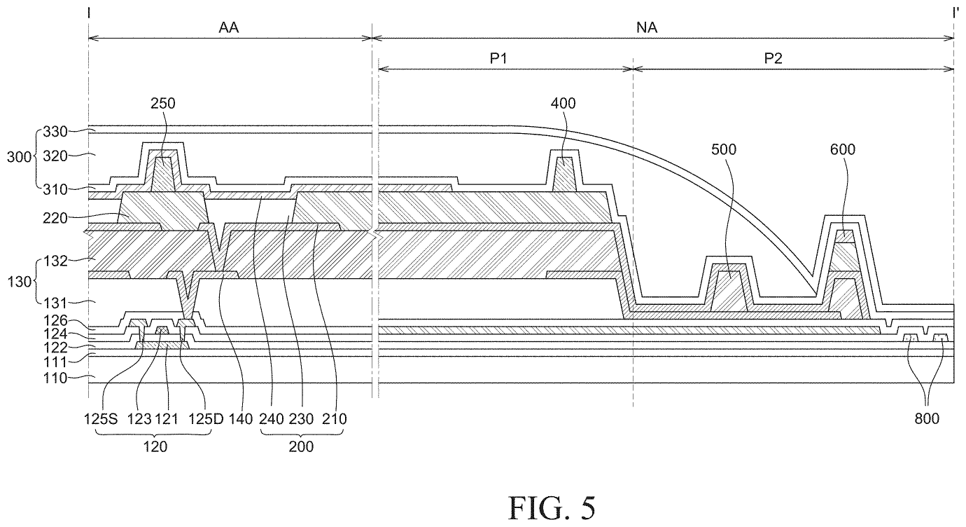

Hereinafter, another example embodiment of the present disclosure will be described with reference to FIG. 5.

A light emitting display apparatus 100 of FIG. 5 is substantially the same as the display apparatus of FIG. 3 except for a second pattern 500 so that a redundant description will be omitted or will be briefly provided.

FIG. 5 is a cross-sectional view of a light emitting display apparatus according to another example embodiment of the present disclosure.

Referring to FIG. 5, a light emitting display apparatus 100 according to another example embodiment of the present disclosure includes a substrate 110 which includes an active area AA and a non-active area NA, a planarization layer 130, a protection layer 300, a first pattern 400, a second pattern 500, and a dam 600.

The second pattern 500 can be disposed as a multi-layer using at least one material. The second pattern 500 can be formed of the same material as the planarization layer 130 of the active area AA and can be simultaneously formed with the planarization layer 130, but is not limited thereto.

When two planarization layers 130 are provided, the planarization layers can include at least one of a first planarization layer 131 and a second planarization layer 132.

Therefore, the second pattern 500 can be formed of the same material as the first planarization layer 131 or the second planarization layer 132 and simultaneously formed with the first planarization layer 131 or the second planarization layer 132, but is not limited thereto.

The second pattern 500 can be disposed as a single layer of the first planarization layer 131 or the second planarization layer 132 or can be disposed as a double layer of the first planarization layer 131 and the second planarization layer 132. Also, the second pattern 500 can include in its structure the same materials that form the first pattern 400 and the dam 600.

When the second pattern 500 is formed simultaneously with the planarization layer 130 disposed in the active area AA, the same material as the anode electrode 210 disposed in the active area AA on the second pattern 500 or a material used for the process of forming the anode electrode 210 can be further disposed on the second pattern 500. Meanwhile, when a material of the anode electrode 210 is disposed in the non-active area NA, at least one of the second pattern 500 and the dam 600 can be disposed on the material of the anode electrode 210 in the non-active area NA. The material of the anode electrode 210 in the non-active area NA can be referred to as an auxiliary electrode or an auxiliary pattern. The auxiliary electrode can be electrically isolated from the anode electrode 200, and current need not flow in the auxiliary electrode, but such is not required. In other embodiments, the auxiliary electrode can be electrically connected to another structure, such as the anode electrode 200, or a current may flow in the auxiliary electrode. The material of the anode electrode 210 in the non-active area NA can be continuous or discontinuous in the non-active area NA, whereby the material of the anode electrode 210 in the non-active area NA can be present in all of the non-active area NA or in discrete portions or a portion of the non-active area NA. The at least one of the second pattern 500 and the dam 600 can be on or in contact (such as entirely or partially) with at least a portion of the material of the anode electrode 210 in the non-active area NA. In various embodiments of the present disclosure, the material of the anode electrode 210 in the non-active area NA can be on or in contact (such as entirely or partially) with at least one of a bottom, a side, a top of at least one of the at least one of the second pattern 500 and the dam 600. Meanwhile, the material of the anode electrode 210 in the non-active area NA can be located above, below or through at least one of the second pattern 500 and the dam 600. For example, the material of the anode electrode 210 in the non-active area NA can cover, partially cover, or be interposed between segments of the second pattern 500, or segments of the dam 600, or segments of both.

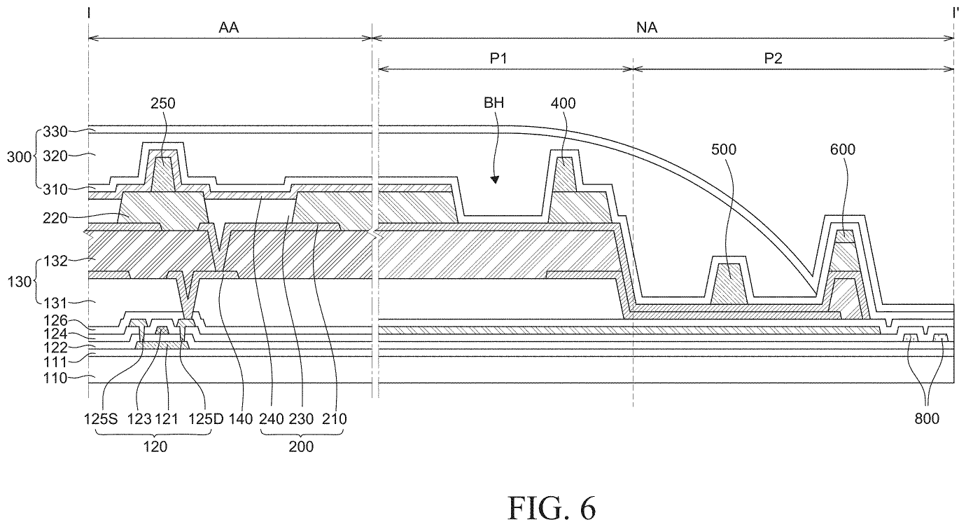

Hereinafter, another example embodiment of the present disclosure will be described with reference to FIG. 6.

A light emitting display apparatus 100 of FIG. 6 is substantially the same as the display apparatus of FIG. 3 except for a buffer hole BH so that a redundant description will be omitted or will be briefly provided.

FIG. 6 is a cross-sectional view of a light emitting display apparatus according to another example embodiment of the present disclosure.

Referring to FIG. 6, a light emitting display apparatus 100 according to another example embodiment of the present disclosure includes a substrate 110 which includes an active area AA and a non-active area NA, a planarization layer 130, a protection layer 300, a first pattern 400, a second pattern 500, a dam 600, and a buffer hole BH.

The buffer hole BH can be disposed on the planarization layer 130 or the anode electrode 210 in the first part P1 of the non-active area NA.

The buffer hole BH can be disposed along the periphery of the active area AA. For example, the buffer hole BH can be disposed between the active area AA and the first pattern 400. The buffer hole BH can be a hole or a first hole among many holes, but reference to the buffer hole BH is not limited by the terminology used to refer to the buffer hole BH.

The buffer hole BH can be formed by the same process for forming the bank hole in the bank layer 220, and which exposes a portion of the anode electrode 210 corresponding to the emission area that is in the active area AA, but is not limited thereto.

At least one buffer hole BH can be disposed. For example, the buffer hole BH can be formed by etching the bank layer 220 to suppress the overflowing of the organic material of the second protection layer 320 beyond the first pattern 400. For example, the buffer hole BH is configured so that an amount of the organic material of the second protection layer 320 overflowing the first pattern 400 is reduced and a spreading (or flowing) distance of the organic material of the second protection layer 320 can be further effectively controlled. Accordingly, the buffer hole BH is configured so that the limitation such as the driving failure which may be caused by the second protection layer 320 intruding into the non-active area NA can be suppressed. Further, a buffer space or a safety margin can be ensured in consideration of a deviation of an applied amount of the second protection layer 320 so that a light emitting display apparatus which has a thin bezel can be provided by minimizing a design margin of the second protection layer 320.

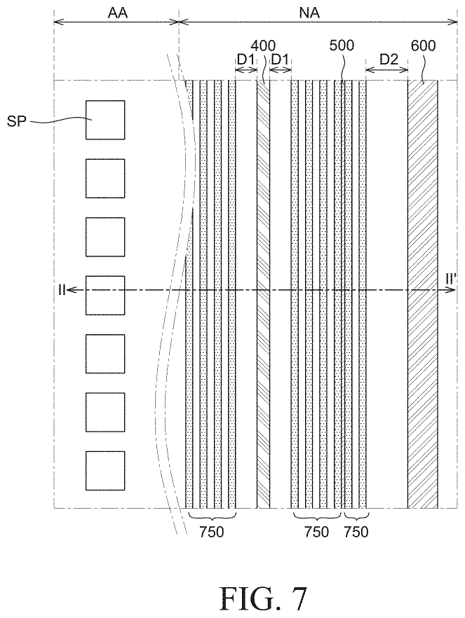

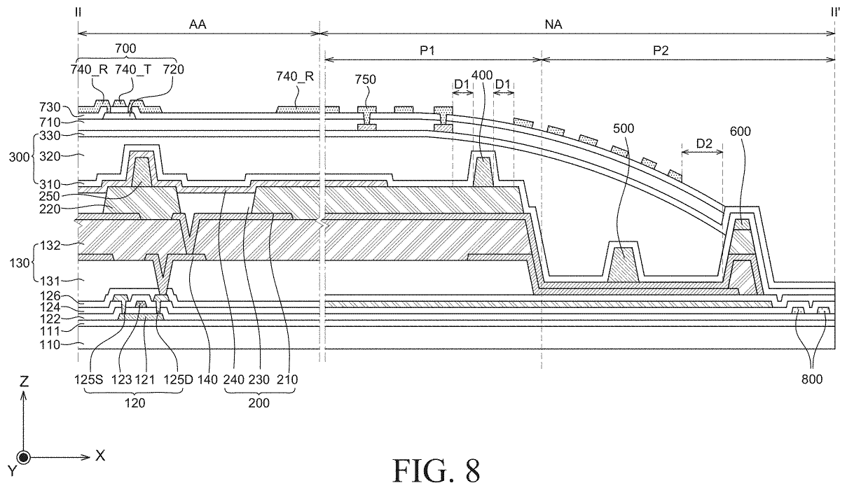

Hereinafter, another example embodiment of the present disclosure will be described with reference to FIGS. 7 and 8.

A light emitting display apparatus 100 of FIGS. 7 and 8 is substantially the same as the light emitting display apparatus of FIG. 3 except for a touch sensor layer 700 and a touch line 750 so that a redundant description will be omitted or will be briefly provided.

FIG. 7 is a plan view of an outer peripheral area of a light emitting display apparatus including a touch sensor layer and a touch line according to another example embodiment of the present disclosure. FIG. 8 is a cross-sectional view of an outer peripheral area of a light emitting display apparatus including a touch sensor layer and a touch line according to another example embodiment of the present disclosure.

Referring to FIGS. 7 and 8, a touch sensor layer 700 and a touch line 750 can be disposed on the protection layer 300.

The touch sensor layer 700 can be disposed in the active area AA. The touch sensor layer 700 can include a first touch electrode 740_R, a second touch electrode 740_T, a first touch connection electrode 720, and a second touch connection electrode.

The first touch electrode 740_R, the second touch electrode 740_T, the first touch connection electrode 720, and the second touch connection electrode disposed in the active area AA can be formed with a mesh pattern in which metal lines having a small line width intersect each other. The mesh pattern can have a rhombus shape, but various shapes are possible. For example, a shape of the mesh pattern can be a rectangle, a pentagon, a hexagon shape, a circle, or an oval, but is not limited thereto.

The first touch electrode 740_R, the second touch electrode 740_T, the first touch connection electrode 720, and the second touch connection electrode can be disposed using an opaque conductive material having a low resistance. For example, the first touch electrode 740_R, the second touch electrode 740_T, the first touch connection electrode 720, and the second touch connection electrode can have a single layer or a multiple-layered structure formed of a metal material such as molybdenum (Mo), silver (Ag), titanium (Ti), copper (Cu), aluminum (Al), titanium/aluminum/titanium (Ti/Al/Ti), and molybdenum/aluminum/molybdenum (Mo/Al/Mo). However, it is not limited thereto.

An opening can be formed in the mesh pattern of the first touch electrode 740_R and the second touch electrode 740_T. The opening can correspond to the sub pixel SP. For example, the light emitting diode layer 200 can be disposed in the opening.

The first touch electrode 740_R, the second touch electrode 740_T, the first touch connection electrode 720, and the second touch connection electrode do not overlap red (R), green (G), and blue (B) light emission areas, but overlap the bank layer 220 formed in the non-emission area. Therefore, even though the electrodes are formed of the opaque conductive material, the degradation of the aperture and the transmittance can be suppressed.

A first touch block Rx configured by at least one first touch electrode 740_R and a first touch connection electrode 720 which connects the plurality of first touch electrodes 740_R can be included. At least one first touch block Rx extends along the first direction (or an X-axis direction). The plurality of first touch blocks Rx can be disposed with a predetermined interval.

A second touch block Tx configured by at least one second touch electrode 740_T and a second touch connection electrode which connects the plurality of second touch electrodes 740_T can be included. At least one second touch block Tx extends along the second direction (or a Y-axis direction). The plurality of second touch blocks Tx can be disposed with a predetermined interval.

The first touch block Rx and the second touch block Tx can be disposed to be spaced apart from each other with a predetermined interval. Therefore, the first touch block Rx and the second touch block Tx can be electrically isolated.

The first touch block Rx and the second touch block Tx are connected to the touch driver by means of the touch line 750 to transmit or receive signals. For example, the touch driver can receive a touch sensing signal from the first touch block Rx or the first touch electrode 740_R. Further, the touch driver can transmit a touch driving signal to the second touch block Tx or the second touch electrode 740_T. The touch driver can sense the touch of the user using a mutual capacitance between the first touch block Rx or the plurality of first touch electrodes 740_R and the second touch block Tx or the plurality of second touch electrodes 740_T. For example, when the touch operation is performed in the light emitting display apparatus 100, the capacitance change can be caused between the first touch block Rx or the first touch electrodes 740_R and the second touch block Tx or the second touch electrodes 740_T. The touch driver can sense the capacitance change to detect a touch coordinate.

A touch buffer layer 710 can be disposed on the protection layer 300. The touch buffer layer 710 can block a liquid chemical (developer or etchant) used during the process of manufacturing a touch sensor layer 700 or moisture from the outside from being permeated into the light emitting diode layer 200 including an organic material. Further, the touch buffer layer 710 can suppress the disconnection of the plurality of touch electrodes disposed thereabove due to the external impact.

The touch buffer layer 710 can be formed of a single layer or a multi-layer formed of any one of silicon oxide SiOx or silicon nitride SiNx or an alloy thereof, but is not limited thereto. Alternatively, the touch buffer layer 710 can be formed of an acryl resin, epoxy resin, or siloxane-based material, but is not limited thereto.

The first touch connection electrode 720 can be disposed in the active area AA on the touch buffer layer 710.

The first touch connection electrode 720 disposed in the active area AA can be disposed between the first touch electrodes 740_R adjacent in the first direction (or the X-axis direction). The first touch connection electrode 720 can electrically connect the plurality of first touch electrodes 740_R which is spaced apart in the first direction (or the X-axis direction) to be adjacent.

The first touch connection electrode 720 can be disposed so as to overlap the second touch connection electrode which connects the second touch electrodes 740_T adjacent in the second direction (or the Y-axis direction). The first touch connection electrode 720 and the second touch connection electrode are formed on different layers to be electrically insulated.

A touch insulating layer 730 can be disposed on the touch buffer layer 710 and the first touch connection electrode 720. The touch insulating layer 730 can be formed in the active area AA and the non-active area NA.

The touch insulating layer 730 can electrically insulate the first touch connection electrode 720 from the second touch electrode 740_T and the second touch connection electrode.

The touch insulating layer 730 can include a hole to electrically connect the first touch electrode 740_R and the first touch connection electrode 720.

The touch insulating layer 730 can be formed by a single layer of silicon nitride SiNx or silicon oxide SiOx or a multi-layer thereof, but is not limited thereto.

The first touch electrode 740_R, the second touch electrode 740_T, and the second touch connection electrode can be disposed on the touch insulating layer 730 in the active area AA.

The first touch electrode 740_R and the second touch electrode 740_T can be disposed to be spaced apart from each other with a predetermined interval. At least one first touch electrode 740_R adjacent in the first direction (or the X-axis direction) can be formed to be spaced apart from each other. At least one first touch electrode 740_R adjacent to each other in the first direction (or the X-axis direction) can be connected to the first touch connection electrode 720 disposed between the first touch electrodes 740_R, respectively. For example, each of the first touch electrodes 740_R can be connected to the first touch connection electrodes 720 by means of the hole of the touch insulating layer 730. The second touch electrode 740_T adjacent in the second direction (or the Y-axis direction) can be connected by the second touch connection electrode. The second touch electrode 740_T and the second touch connection electrode can be formed on the same layer.

A touch planarization layer can be disposed on the touch insulating layer 730, the first touch electrode 740_R, the second touch electrode 740_T, and the second touch connection electrode.

The touch planarization layer can be disposed so as to cover the touch insulating layer 730, the first touch electrode 740_R, the second touch electrode 740_T, and the second touch connection electrode. Additionally layers or materials can be provided over the touch planarization layer.

The touch planarization layer can be formed of at least one of an acrylic resin, an epoxy resin, a phenol resin, a polyamide resin, a polyimide resin, an unsaturated polyester resin, a polyphenylene resin, and a polyphenylene sulfide resin, but is not limited thereto.

A touch line 750 can be disposed in the non-active area NA. The touch line 750 can include a first touch line 751 and a second touch line 752. The touch line 750 can be disposed as a double line of the first touch line 751 and the second touch line 752.

The first touch line 751 can be disposed on the touch buffer layer 710. The first touch line 751 stably supplies a signal even though the second touch line 752 is disconnected by the external impact and can be electrically connected to the second touch line 752 so as to reduce a resistance of the second touch line 752 which transmits a signal of the touch driver to the first touch block Rx and the second touch block Tx. For example, the first touch line 751 can be electrically connected to the second touch line 752 by means of the hole of the touch insulating layer 730.

A touch insulating layer 730 can be disposed on the first touch line 751. When the touch insulating layer 730 is formed on the first touch connection electrode 720 disposed in the active area AA, the touch insulating layer 730 can be simultaneously formed of the same material by the same process, but it is not necessarily limited thereto. Therefore, a separate process can be performed during the process and the patterning can be performed.

At least one part of the first touch line 751 and the second touch line 752 can be disposed to overlap.

The touch insulating layer 730 can further include a plurality of holes which exposes at least a part of the first touch line 751.

The first touch line 751 disposed below the touch insulating layer 730 and the second touch line 752 disposed above the touch insulating layer 730 can be electrically connected by means of the hole of the touch insulating layer 730.

The second touch line 752 can be disposed on the touch insulating layer 730. The second touch line 752 can transmit a signal from an external module which is attached or bonded to the touch driver to the first touch block Rx and the second touch block Tx.

The second touch line 752 can be formed of the same material and by the same process as the first touch electrode 740_R, the second touch electrode 740_T, and the second touch connection electrode disposed in the active area AA, but is not limited thereto.

A touch planarization layer can be further disposed on the second touch line 752. The touch planarization layer can be disposed to cover the second touch line 752. The touch planarization layer can planarize an upper portion of the second touch line 752.

The touch planarization layer can be formed of the same material and by the same process as the touch planarization layer disposed in the active area AA, but is not limited thereto.

The light emitting display apparatus 100 in which a plurality of touch lines 750 is disposed on the protection layer 300 has a limitation in that a touch sensitivity at an outer peripheral area A of the light emitting display apparatus 100 is lowered due to a low thickness and/or steep inclination and a step of the protection layer 300 in the non-active area NA adjacent to the active area AA of the light emitting display apparatus 100. For example, the protection layer 300 of the active area AA has a uniform thickness. To the contrary, in the protection layer 300 formed in the non-active area NA adjacent to the active area AA, a steep inclination and a step can be formed to cause an elevation change because the planarization layer, the insulating layer, and the metal line disposed below the protection layer 300 can be etched. Therefore, there is a limitation in that the moving speed of the organic material of the second protection layer 320 is increased so that a thickness is reduced before the second protection layer 320 is hardened and the second protection layer 320 is not applied.

The protection layer 300 formed to have a small thickness in the non-active area NA adjacent to the active area AA causes the electric field interference of the electrodes and the wiring lines disposed above and below the protection layer 300, which results in the degradation of the display quality and the lowering of the touch sensitivity.

Further, when the touch line 750 is manufactured with the steep inclination and step of the protection layer 300 in the non-active area NA, if the touch line 750 is formed in an area in which the inclination or the step of the protection layer 300 is formed, there is a limitation such as the loss or disconnection of the touch line.

Therefore, the inventors of the present disclosure conducted several experiments to reduce the lowering of the display quality and the touch sensitivity in the non-active area NA adjacent to the active area AA. Several experiments have been conducted to improve a display quality and improve a touch sensitivity by minimizing electric field interference of the electrode disposed above and below the protection layer 300 in the non-active area NA adjacent to the active area AA.

The first pattern 400 formed in the first part P1 of the non-active area NA adjacent to the active area AA suppresses the flow of the organic material of the second protection layer 320 to make the thickness of the second protection layer 320 formed in the first part P1 large. The second protection layers 320 are formed to have similar thicknesses in the first parts P1 in the active area AA and the non-active area NA. Therefore, it is possible to suppress the increase of the parasitic capacitance Cp formed in the non-active area NA adjacent to the active area AA in the related art and improve the display quality and a sensitivity of the touch sensing.

The touch line 750 can be disposed to overlap the first pattern 400, the second pattern 500, and the dam 600.

The touch line 750 can be disposed to be spaced apart from the first pattern 400, the second pattern 500, and the dam 600 without overlapping at least a part thereof. For example, the touch line 750 can be disposed so as not to at least partially overlap the first pattern 400 and the dam 600. The touch line 750 can be disposed to at least partially overlap the second pattern 500.

The touch line 750 can be spaced apart from the first pattern 400 with a first distance D1 therebetween and can be spaced apart from the dam 600 with a second distance D2 therebetween. The first distance D1 and the second distance D2 can be equal to each other or different from each other. When the first distance D1 and the second distance D2 are different, the second distance D2 can be larger than the first distance D1.

The example embodiments of the present disclosure can also be described as follows:

According to an aspect of the present disclosure, there is provided a light emitting display apparatus. The light emitting display apparatus comprises a substrate including an active area and a non-active area adjacent to the active area; a planarization layer in the active area and a first part of the non-active area; a bank layer, a light emitting diode layer, and a first pattern disposed on the planarization layer; and a second pattern and a dam disposed in a second part adjacent to the first part of the non-active area and having different heights.

The planarization layer can extend from the active area to the first part of the non-active area.

The second pattern can be spaced apart from the first pattern and the dam and can be disposed between the first pattern and the dam.

The light emitting display apparatus can further comprise a spacer disposed on the bank. The first pattern can be located on the same layer as the spacer and can be formed of the same material.

The second pattern can be formed of the same material as the planarization layer.

The light emitting display apparatus can further comprise at least one metal layer disposed above the second pattern.

Vertical heights of the first pattern and the second pattern can be lower than a vertical height of the dam.

The dam can include the planarization layer, the bank layer, and the spacer.

The number of each of the first pattern and the second pattern can be two or larger.

The number of dams can be smaller than the number of the first patterns and the second patterns.

The light emitting display apparatus can further comprise a protection layer disposed in the active area and the non-active area.

The protection layer can include a second protection layer configured by an organic material.

At least a part of the second protection layer can be disposed between the second pattern and the dam.

The light emitting display apparatus can further comprise a touch line disposed on the protection layer.

The touch line can be spaced apart from a part of at least one of the first pattern and the dam.

The touch line can overlap at least a part of the second pattern.

The light emitting display apparatus can further comprise a first touch electrode and a second touch electrode disposed in the active area.

The presence of touch and a touch position can be sensed by sensing a variation of a mutual capacitance Cm formed between the first touch electrode and the second touch electrode.

The light emitting display apparatus can further comprise a driving circuit. The first pattern, the second pattern, and the dam can be disposed between the active area and the driving circuit.

The driving circuit can include at least one multiplexer MUX, an electrostatic discharge ESD circuit, a high potential voltage line VDD, or a low potential voltage line VSS and the first pattern, the second pattern, and the dam can be disposed between the active area and the multiplexer MUX, the electrostatic discharge ESD circuit, the high potential voltage line VDD, or the low potential voltage line VSS.

The light emitting display apparatus can further comprise a gate driving circuit disposed in the non-active area. The gate driving circuit can be disposed between the active area and the first pattern, the second pattern, or the dam.

According to an aspect of the present disclosure, a light emitting display apparatus can include a substrate including an active area and a non-active area enclosing the active area; a planarization layer in the active area; a spacer on the planarization layer and in the active area; a first pattern on the planarization layer and in the non-active area; and a second pattern in the non-active area.

The non-active area can include a first part that is adjacent the active area, and a second part that is outward of the first part, and a boundary between the first part and the second part, and the second part of the non-active area does not include the planarization layer.

The non-active area can include a first part, and a second part outward of the first part, and a dam is further disposed in the second part of the non-active area.

The light emitting display apparatus can further include a dam in the non-active area; and a protection layer in the active area and the non-active area, and disposed on the first pattern, the second pattern and the dam.

The protection layer inward of the first pattern and the protection layer outward of the first pattern can have an elevation difference.

The light emitting display apparatus can further include an anode electrode on the planarization layer, a bank layer on the anode electrode, a light emitting diode layer on the anode electrode, and a cathode electrode on the light emitting diode layer, a material of the anode electrode can be disposed in the non-active area, and the second pattern and the dam can be on the material of the anode electrode in the non-active area.

A surface of the protection layer between the spacer and the first pattern includes a planar portion, and the surface of the protection layer between the first pattern and the second pattern or the dam includes an uneven portion.

A thickness of the protection layer between the spacer and the first pattern can be different from the thickness of the protection layer between the first pattern and the second pattern or between the second pattern and the dam.

The protection layer an include a first protection layer and a second protection layer, and a thickness of the second protection layer changes in extending outward from the active area to the non-active area.

The second protection layer need not be disposed outward of the dam.

A thickness of the planarization layer over the spacer can be about the same as a thickness of the planarization layer over the first pattern.

A thickness of the protection layer over the spacer can be the same as the thickness of the protection layer over the first pattern and the second pattern.

A thickness of the protection layer over the spacer can be different from the thickness of the protection layer over at least one of the second pattern and the dam.

The light emitting display apparatus can further include an anode electrode on the planarization layer, a bank layer on the anode electrode, a light emitting diode layer on the anode electrode, and a cathode electrode on the light emitting diode layer, a material of the anode electrode can be disposed in the non-active area, and the second pattern can be on the material of the anode electrode.

The second pattern can contact an auxiliary electrode of an anode electrode located in the non-active area.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A light emitting display apparatus, comprising:
a substrate including an active area and a non-active area adjacent to the active area;
a planarization layer in the active area and in a first part of the non-active area;
a bank layer, a light emitting diode layer, and a first pattern disposed on the planarization layer; and
a second pattern and a dam disposed in a second part adjacent to the first part of the non-active area, the second pattern and the dam having different heights.

2. The light emitting display apparatus according to claim 1, wherein the planarization layer extends from the active area to the first part of the non-active area.

3. The light emitting display apparatus according to claim 1, wherein the second pattern is spaced apart from the first pattern and the dam and is disposed between the first pattern and the dam.

4. The light emitting display apparatus according to claim 1, further comprising:
a spacer disposed on the bank layer,
wherein the first pattern is located on a same layer as the spacer and is formed of the same material as the first pattern.

5. The light emitting display apparatus according to claim 1, wherein the second pattern is formed a same material as the planarization layer.

6. The light emitting display apparatus according to claim 5, further comprising:
at least one metal layer disposed on the second pattern.

7. The light emitting display apparatus according to claim 1, wherein heights of the first pattern and the second pattern are different than a height of the dam in a cross sectional view.

8. The light emitting display apparatus according to claim 4, wherein the dam includes materials of the planarization layer, the bank layer, and the spacer.

9. The light emitting display apparatus according to claim 1, wherein a number of each of the first pattern and the second pattern is two or larger.

10. The light emitting display apparatus according to claim 1, wherein a number of the dam is smaller than the number of the first pattern and the number of the second pattern.

11. The light emitting display apparatus according to claim 1, further comprising:
a protection layer disposed in the active area and the non-active area.

12. The light emitting display apparatus according to claim 11, wherein the protection layer includes a second protection layer including an organic material.

13. The light emitting display apparatus according to claim 12, wherein at least a part of the second protection layer is disposed between the second pattern and the dam.

14. The light emitting display apparatus according to claim 11, further comprising:
a touch line disposed on the protection layer.

15. The light emitting display apparatus according to claim 14, wherein the touch line is spaced apart from a part of at least one of the first pattern and the dam.

16. The light emitting display apparatus according to claim 14, wherein the touch line overlaps at least a part of the second pattern.

17. The light emitting display apparatus according to claim 1, further comprising:
a first touch electrode and a second touch electrode disposed in the active area.

18. The light emitting display apparatus according to claim 17, wherein a presence of a touch and a touch position of the touch is sensed by sensing a variation of a mutual capacitance formed between the first touch electrode and the second touch electrode.

19. The light emitting display apparatus according to claim 1, further comprising:
a driving circuit,
wherein the first pattern, the second pattern, and the dam are disposed between the active area and the driving circuit.

20. The light emitting display apparatus according to claim 19, wherein the driving circuit includes at least one multiplexer (MUX), an electrostatic discharge (ESD) circuit, a high potential voltage line (VDD), or a low potential voltage line (VSS), and
wherein the first pattern, the second pattern, and the dam are disposed between the active area and the multiplexer (MUX), the electrostatic discharge (ESD) circuit, the high potential voltage line (VDD), or the low potential voltage line (VSS).

21. The light emitting display apparatus according to claim 1, further comprising:
a gate driving circuit disposed in the non-active area,
wherein the gate driving circuit is disposed between the active area and the first pattern, the active area and the second pattern, or the active area and the dam.

22. A light emitting display apparatus, comprising:
a substrate including an active area and a non-active area enclosing the active area;
a planarization layer in the active area;
a spacer on the planarization layer and in the active area;
a first pattern on the planarization layer and in the non-active area; and
a second pattern in the non-active area.

23. The light emitting display apparatus according to claim 22, wherein the non-active area includes a first part that is adjacent the active area, and a second part that is outward of the first part, and a boundary between the first part and the second part, and
wherein the second part of the non-active area does not include the planarization layer.

24. The light emitting display apparatus according to claim 22, wherein the non-active area includes a first part, and a second part outward of the first part, and
wherein a dam is further disposed in the second part of the non-active area.

25. The light emitting display apparatus according to claim 22, further comprising:
a dam in the non-active area; and
a protection layer in the active area and the non-active area, and disposed on the first pattern, the second pattern and the dam.

26. The light emitting display apparatus according to claim 25, wherein the protection layer inward of the first pattern and the protection layer outward of the first pattern have an elevation difference.

27. The light emitting display apparatus according to claim 25, further comprising:
an anode electrode on the planarization layer, a bank layer on the anode electrode, a light emitting diode layer on the anode electrode, and a cathode electrode on the light emitting diode layer,
wherein a material of the anode electrode is disposed in the non-active area, and
wherein the second pattern and the dam is on the material of the anode electrode in the non-active area.

28. The light emitting display apparatus according to claim 25, wherein a surface of the protection layer between the spacer and the first pattern includes a planar portion, and
wherein the surface of the protection layer between the first pattern and the second pattern or the dam includes an uneven portion.

29. The light emitting display apparatus according to claim 25, wherein a thickness of the protection layer between the spacer and the first pattern is different from the thickness of the protection layer between the first pattern and the second pattern or between the second pattern and the dam.

30. The light emitting display apparatus according to claim 25, wherein the protection layer includes a first protection layer and a second protection layer, and
wherein a thickness of the second protection layer changes in extending outward from the active area to the non-active area.

31. The light emitting display apparatus according to claim 30, wherein the second protection layer is not disposed outward of the dam.

32. The light emitting display apparatus according to claim 22, wherein a thickness of the planarization layer over the spacer is about the same as a thickness of the planarization layer over the first pattern.

33. The light emitting display apparatus according to claim 25, wherein a thickness of the protection layer over the spacer is the same as the thickness of the protection layer over the first pattern and the second pattern.

34. The light emitting display apparatus according to claim 25, wherein a thickness of the protection layer over the spacer is different from the thickness of the protection layer over at least one of the second pattern and the dam.

35. The light emitting display apparatus according to claim 22, further comprising:
an anode electrode on the planarization layer, a bank layer on the anode electrode, a light emitting diode layer on the anode electrode, and a cathode electrode on the light emitting diode layer,
wherein a material of the anode electrode is disposed in the non-active area, and
wherein the second pattern is on the material of the anode electrode.

36. The light emitting display apparatus according to claim 22, wherein the second pattern contacts an auxiliary electrode of an anode electrode located in the non-active area.
